(19) United States
(12) Patent Application Publication
(10) Pub. No.: US 2024/0087998 A1
(43) Pub. Date: Mar. 14, 2024

(54) SEMICONDUCTOR PACKAGE

(71) Applicant: SAMSUNG ELECTRONICS CO., LTD., Suwon-si (KR)

(72) Inventor: Kilsoo KIM, Suwon-si (KR)

(73) Assignee: SAMSUNG ELECTRONICS CO., LTD., Suwon-si (KR)

(21) Appl. No.: 18/234,092

(22) Filed: Aug. 15, 2023

(30) Foreign Application Priority Data
Sep. 13, 2022 (KR) 10-2022-0115105

(51) Int. Cl. H01L 23/498; H01L 23/00; H01L 23/538; H01L 25/10; H10B 80/00

(52) U.S. Cl. CPC H01L 23/49811; H01L 23/49838; H01L 23/5386; H01L 24/16; H01L 25/105; H10B 80/00; H01L 24/48; H01L 2224/16227; H01L 2224/48105; H01L 2224/48145; H01L 2225/1005; H01L 2924/1438

(57) ABSTRACT

A semiconductor package including a first semiconductor device including a semiconductor chip; an interposer including silicon and electrically connected to the first semiconductor device, wherein the first semiconductor is provided on the interposer; a second semiconductor device; and a substrate, wherein the interposer and the second semiconductor device, are provided on the substrate apart from each other, and wherein the interposer is electrically connected to the second semiconductor device; wherein a first volume of a first shape, in which the first semiconductor device overlaps an upper surface of the substrate, is less than or equal to a second volume of a second shape, in which the interposer overlaps an upper surface of the substrate.

### CROSS-REFERENCE TO RELATED APPLICATION

This application claims priority to Korean Patent Application No. 10-2022-0115105, filed on Sep. 13, 2022, in the Korean Intellectual Property Office, the disclosure of which is incorporated by reference herein in its entirety.

### BACKGROUND

The disclosure relates to a semiconductor device, and more particularly, to a semiconductor device including an interposer.

With the rapid development of the electronic industry and the needs of users, electronic products are becoming smaller and lighter, and to this end, semiconductor packages mounted on electronic products may be required to include various functions while at the same time having a smaller volume. Accordingly, semiconductor devices including a plurality of semiconductor chips are being developed.

### SUMMARY

One or more example embodiments includes mounting a semiconductor package on package substrates by reducing the effect of warpage of semiconductor devices, improve the bandwidths of the semiconductor packages, and miniaturize the semiconductor packages.

According to an aspect of an example embodiment, a semiconductor package includes a first semiconductor device comprising a semiconductor chip; an interposer comprising silicon and electrically connected to the first semiconductor device, wherein the first semiconductor device is provided on the interposer; a second semiconductor device; and a substrate, wherein the interposer and the second semiconductor device, are provided on the substrate apart from each other, and wherein the interposer is electrically connected to the second semiconductor device; wherein a first volume of a first shape, in which the first semiconductor device overlaps an upper surface of the substrate, is less than or equal to a second volume of a second shape, in which the interposer overlaps the upper surface of the substrate.

According to an aspect of an example embodiment, a semiconductor package includes: a first printed circuit board (PCB) substrate electrically connected to the outside; a memory package comprising the first printed circuit board (PCB) substrate and memory chips stacked on the first printed circuit board (PCB) substrate; a silicon interposer electrically connected to the first printed circuit board (PCB) substrate; a logic chip spaced apart from the memory package and the silicon interposer; and a second printed circuit board (PCB) substrate having the silicon interposer and the logic chip provided thereon, and electrically connected to the silicon interposer and the logic chip.

According to an aspect of an example embodiment, a semiconductor package includes: a first printed circuit board (PCB) substrate; a memory package comprising the first printed circuit board (PCB) substrate and memory chips stacked on the first printed circuit board (PCB) substrate; a silicon interposer electrically connected to the first printed circuit board (PCB) substrate; a logic chip spaced apart from the memory package and the silicon interposer; and a second printed circuit board (PCB) substrate comprising the silicon interposer and the logic chip mounted thereon, and electrically connected to the silicon interposer and the logic chip, wherein a plurality of first connection terminals configured to be electrically connected to the first PCB substrate are provided on an upper surface of the silicon interposer, and a plurality of third connection terminals configured to be electrically connected to the second PCB substrate are provided under a lower surface of the silicon interposer, and wherein a curvature of the first printed circuit board (PCB) substrate is equal to or different from a curvature of the second printed circuit board (PCB) substrate, and a curvature of the silicon interposer is less than the curvature of the first printed circuit board (PCB) substrate and the curvature of the second printed circuit board (PCB) substrate.

### BRIEF DESCRIPTION OF DRAWINGS

The above and other aspects and features will be more apparent from the following description of example embodiments, taken in conjunction with the accompanying drawings, in which:

FIG. 1 is a cross-sectional view of a semiconductor package according to an embodiment;

FIG. 2 is a cross-sectional view of a portion of a semiconductor package, according to an embodiment;

FIG. 3 is a diagram illustrating a semiconductor package according to an embodiment of FIG. 1, viewed from above in a −Z axis direction;

FIG. 4 is a side view of a conventional semiconductor package;

FIG. 5 is a view of a conventional semiconductor package of FIG. 4, viewed from above in the −Z axis direction;

FIG. 6 is a cross-sectional view of a semiconductor package, according to an embodiment;

FIG. 7 is a diagram of a semiconductor package according to an embodiment, viewed from above in the −Z axis direction;

FIG. 8 is a side view of a semiconductor package, according to an embodiment; and

FIG. 9 is a diagram of a semiconductor package according to an embodiment, viewed from above in the −Z axis direction.

### DETAILED DESCRIPTION OF EMBODIMENTS

Example embodiments will be described more fully with reference to the accompanying drawings, in which example embodiments are shown. Embodiments described herein are provided as examples, and thus, the present disclosure is not limited thereto, and may be realized in various other forms. Each embodiment provided in the following description is not excluded from being associated with one or more features of another example or another embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. Although the terms first, second, and the like may be used herein to describe various elements, components, steps and/or operations, these terms may be used only to distinguish one element, component, step or operation from another element, component, step, or operation.

Identical reference numerals are used for the same constituent elements in the drawings, and duplicate descriptions thereof are omitted.

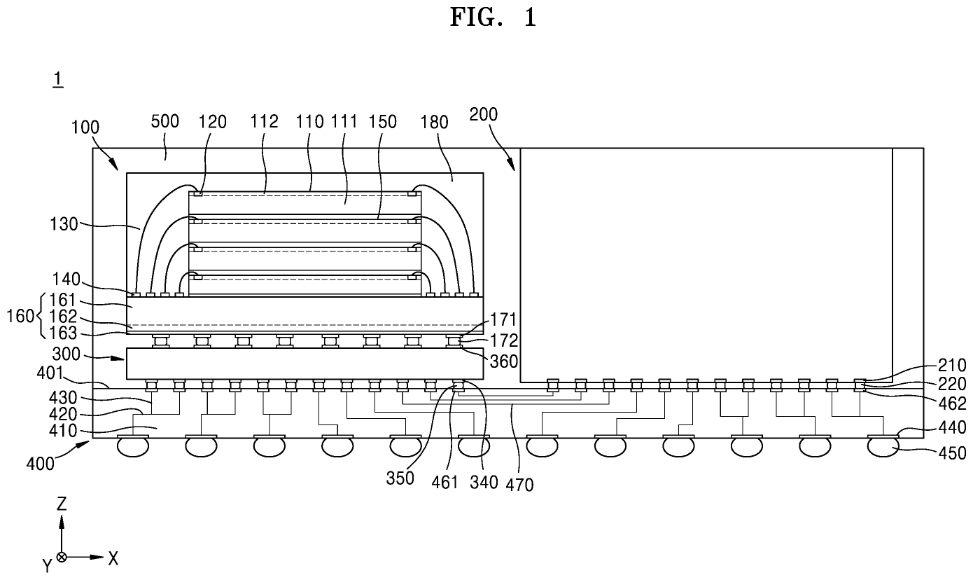

FIG. 1 is a cross-sectional view of a semiconductor package 1 according to an embodiment.

Referring to FIG. 1, the semiconductor package 1 may include a package substrate 400, an interposer 300 mounted on the package substrate 400, a first semiconductor device 100 mounted on the interposer 300, and a second semiconductor device 200. The first semiconductor device 100 may be mounted on an upper surface 401 of the package substrate 400. The second semiconductor device 200 may be mounted on the upper surface 401 of the package substrate 400, while being horizontally apart from the first semiconductor device 100 and the interposer 300. For example, a distance between the first semiconductor device 100 and the second semiconductor device 200 may be the substantially the same as a distance between the interposer 300 and the second semiconductor device 200.

The package substrate 400 may include a printed circuit board (PCB). For example, the package substrate 400 may include a multi-layer PCB. A package substrate layer 410 may include at least one of a phenol resin, epoxy resin, or a polyimide material. The package substrate layer 410 may include at least one material of, for example, flame retardant 4 (FR4), tetrafunctional epoxy, polyphenylene ether, epoxy/polyphenylene oxide, bismaleimide triazine (BT), thermount, cyanate ester, polyimide, and liquid crystal polymer.

A solder resist layer (not illustrated) exposing a plurality of first pads 461, a plurality of second pads 462, and a plurality of external connection pads 440, each of which is arranged on an upper surface of a package substrate layer 410, may be formed on each of the upper and a lower surface of the package substrate layer 410. A plurality of first connection terminals 172 may be attached to a plurality of first pads 461, a plurality of second connection terminals 220 may be attached to a plurality of second pads 462, and a plurality of external connection terminals 450 may be attached to the plurality of external connection pads 440. The plurality of external connection terminals 450 may include, for example, solder balls.

The package substrate 400 may include substrate wirings 420 and 430, which electrically connect a plurality of upper connection pads 462, which may be referred to as second pads 462, to the plurality of external connection pads 440. The substrate wirings 420 and 430 may be arranged on the upper surface, the lower surface, and/or the inside of the package substrate layer 410. The substrate wirings 420 and 430 may include, for example, electronically deposited (ED) copper, a rolled-annealed (RA) copper foil, a stainless steel foil, an aluminum foil, an ultra-thin copper foil, sputtered copper, an copper alloy, etc.

The first semiconductor device 100 may be mounted on the interposer 300. A plurality of lower pads 171 may be arranged on a lower surface of the first semiconductor device 100. The plurality of lower pads 171 may be electrically connected to the semiconductor chips of the first semiconductor device 100. The plurality of lower pads 171 may be respectively electrically connected to a plurality of upper pads 360 on an upper surface of the interposer 300. The plurality of lower pads 171 may be electrically connected to the plurality of upper pads 360 through a plurality of first connection terminals 172, respectively.

The interposer 300 may include an interposer substrate 320 and a plurality of through electrodes 330. In addition, the interposer 300 may further include a redistribution layer 310.

A plurality of lower pads 340 may be on a lower surface of the interposer 300, and may be electrically connected to the plurality of first pads 461 on the upper surface of the package substrate 400. For example, a plurality of connection terminals 350 may be between the plurality of lower pads 340 and the plurality of first pads 461, and electrically connect the plurality of lower pads 340 to the plurality of first pads 461.

The interposer substrate 320 may include, for example, a semiconductor material or an insulating material. In some embodiments, the interposer substrate 320 may include silicon, germanium, silicon-germanium, gallium-arsenide (GaAs), glass, ceramic, etc. The interposer 300 may include the plurality of through electrodes 330 penetrating the interposer substrate 320. The plurality of lower pads 340 and the plurality of connection terminals 350 may be provided for electrical connection with an external device, for example, a PCB.

The plurality of through electrodes 330 may be respectively electrically connected to the plurality of upper pads 360 so that other semiconductor devices may be mounted on the upper surface of the interposer 300. Each of the plurality of through electrodes 330 may protrude above the upper surface of the interposer substrate 320. In FIG. 1, for convenience of illustration, a shape, in which the plurality of through electrodes 330 protrudes above the upper surface of the interposer substrate 320, is not illustrated. The plurality of through electrodes 330 may include one or more of, for example, aluminum (Al), gold (Au), beryllium (Be), bismuth (Bi), cobalt (Co), copper (Cu), hafnium (Hf), indium (In), magnesium (Mg), manganese (Mn), molybdenum (Mo), nickel (Ni), lead (Pb), palladium (Pd), platinum (Pt), rhodium (Rh), rhenium (Re), ruthenium (Ru), tin (Sn), tantalum (Ta), tellurium (Te), titanium (Ti), tungsten (W), zinc (Zn), and zirconium (Zr).

The interposer 300 may further include the redistribution layer 310, and the redistribution layer 310 may be on the upper surface of the interposer substrate 320. The redistribution layer 310 may include contact plugs (not illustrated) and metal horizontal wirings 311. The contact plugs may respectively electrically connect the metal horizontal wirings 311 to the plurality of upper pads 360, which are vertically adjacent to each other. The redistribution layer 310 may further include an interlayer insulating layer 312 to electrically insulate components included therein. The interlayer insulating layer 312 may include silicon oxide, silicon nitride, silicon oxynitride, polymer, or a combination thereof.

The second semiconductor device 200 may be electrically connected to a plurality of lower pads 210 attached to the lower surface of the second semiconductor device 200 via the plurality of second pads 462 on the package substrate 400. For example, the plurality of lower pads 210 may be electrically connected to the plurality of second pads 462 via the plurality of second connection terminals 220. The pitch indicating an interval between the plurality of second connection terminals 220 may be about 50 μm or more, and about 100 μm or less, for example.

A first underfill material layer (not illustrated) surrounding the plurality of first connection terminals 172 may be arranged between the first semiconductor device 100 and the package substrate 400. A second underfill material layer (not illustrated) surrounding the plurality of second connection terminals 220 may be arranged between the second semiconductor device 200 and the package substrate 400.

The first semiconductor device 100 may include a first semiconductor chip 160 and a plurality of second semiconductor chips 110 sequentially stacked on the first semiconductor chip 160. In some embodiments, four or eight second semiconductor chips 110 may be stacked on one first semiconductor chip 160. In some embodiments, each of the plurality of second semiconductor chips 110 may include a memory semiconductor chip including a memory device, and the first semiconductor chip 160 may include a logic semiconductor chip including circuits for controlling a memory device, such as a dynamic random access memory (DRAM) device or a flash memory device.

The first semiconductor chip 160 may be referred to as a base die, a base chip, a controller die, a controller chip, a buffer die, or a buffer chip. The second semiconductor chip 110 may be referred to as a memory die, a memory chip, a core die, or a core chip. In some embodiments, when the second semiconductor chip 110 includes a DRAM device, the second semiconductor chip 110 may be referred to as a DRAM die or a DRAM chip. In some embodiments, when the second semiconductor chip 110 includes a flash memory device, the second semiconductor chip 110 may be referred to as a flash memory die or a flash memory chip.

The first semiconductor chip 160 may include a first semiconductor substrate 161, on which a first semiconductor device 162 is formed on an active surface thereof, and a wiring layer 163 arranged on the active surface of the first semiconductor substrate 161. The first semiconductor chip 160 may have a face down arrangement, in which the active surface of the first semiconductor substrate 161 faces downward.

In an embodiment, an upper surface and a lower surface of a semiconductor chip may refer to an upper side surface and a lower side surface, as shown in the drawings, and a front surface and a rear surface of the semiconductor chip may refer to an active side surface and an inactive side surface of a semiconductor substrate, respectively. For example, in FIG. 1, an upper surface of the first semiconductor chip 160 may be a rear surface, and a lower surface thereof may be a front surface

The first semiconductor substrate 161 may include, for example, a semiconductor material, such as silicon (Si) or germanium (Ge). Alternatively, the first semiconductor substrate 161 may include compound semiconductor materials, such as silicon carbide (SiC), gallium arsenide (GaAs), indium arsenide (InAs), and indium phosphate (InP). The first semiconductor substrate 161 may include a conductive region, for example, a well doped with impurities. The first semiconductor substrate 161 may have various device isolation structures such as a shallow trench isolation (STI) structure.

The first semiconductor substrate 161 may include a first semiconductor device 162 including a plurality of individual devices of various types formed on the active surface of the first semiconductor substrate 161. The plurality of individual devices may include various microelectronic devices, for example, a metal-oxide-semiconductor field effect transistor (MOSFET), such as a complementary metal-insulator-semiconductor (CMOS) transistor, system large scale integration (LSI), an active device, a passive device, etc. The plurality of individual devices may be electrically connected to the conductive region of the first semiconductor substrate 161. The first semiconductor device 162 may further include a conductive wiring or a conductive plug electrically connecting at least two of the plurality of individual devices, or the plurality of individual devices to the conductive region of the first semiconductor substrate 161. In addition, each of the plurality of individual devices may be electrically isolated from another adjacent individual device by an insulating layer.

The wiring layer 163 may include a plurality of conductive wiring patterns (not illustrated) and an inter-wiring insulating layer (not illustrated) around and surrounding the plurality of conductive wiring patterns. The plurality of conductive wiring patterns may include wiring lines and wiring vias. In some embodiments, a plurality of conductive wiring patterns may have multilayer wiring structures including wiring lines and wiring vias at different vertical levels, and an inter-wiring insulating layer may have a multilayer structure, in which a plurality of insulating layers are stacked corresponding to the multilayer wiring structure of the plurality of conductive wiring patterns. The plurality of conductive wiring patterns may include a metal material, such as at least one of aluminum, copper, and tungsten.

The plurality of first connection terminals 172 may be attached onto the plurality of lower pads 171. In some embodiments, the plurality of first connection terminals 172 may include solder balls. The plurality of first connection terminals 172 may electrically connect the first semiconductor device 100 and an external device.

The plurality of second semiconductor chips 110 may be sequentially stacked on the first semiconductor chip 160. The plurality of second semiconductor chips 110 may be sequentially stacked on an inactive surface of the first semiconductor substrate 161. The plurality of second semiconductor chips 110 may be sequentially stacked on the first semiconductor chip 160 in the vertical direction (+Z axis direction). The plurality of second semiconductor chips 110 may be stacked to overlap each other in the vertical direction (+Z axis direction). Edges of each of the plurality of second semiconductor chips 110 may be aligned with each other in the vertical direction (+Z axis direction). Each of a plurality of second semiconductor chips 110 may have a face up arrangement in which an active surface of a second semiconductor substrate 111 faces upward.

Each of a plurality of second semiconductor chips 110 may include a die adhesive film 150, attached to a lower surface thereof, between the plurality of second semiconductor chips 110, and may include the die adhesive film 150 attached to a structure thereunder. For example, the lowest second semiconductor chip 110 among the plurality of second semiconductor chips 110 may be attached onto the first semiconductor chip 160 thereof, with the die adhesive film 150 therebetween, and the others of the plurality of second semiconductor chips 110 may be attached onto the other different second semiconductor chip 110 on the lower side thereof, with the die adhesive film 150 therebetween. The second semiconductor chip 110 and the die adhesive film 150 attached to the lower surface of the second semiconductor chip 110 may have the substantially the same horizontal width and horizontal area.

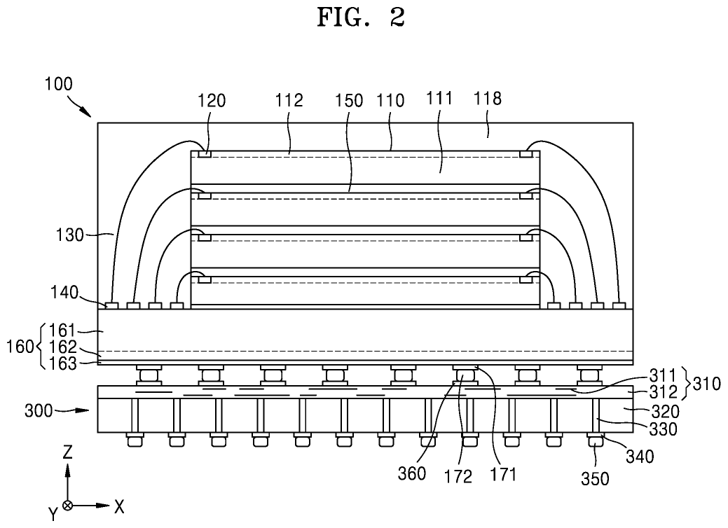

In some embodiments, the horizontal width and the horizontal area of the second semiconductor chip 110 may be less than a horizontal width and a horizontal area of the first semiconductor chip 160. For example, as shown in FIG. 2, the plurality of second semiconductor chips 110 may be stacked on the first semiconductor chip 160 without departing from a plane extending from a side surface of the first semiconductor chip 160. The plurality of second semiconductor chips 110 may have substantially the same horizontal width and horizontal area.

The second semiconductor chip 110 may include the second semiconductor substrate 111, on which a second semiconductor device 112 is formed on an active surface thereof, and a plurality of chip pads 120 arranged on an upper surface thereof. The plurality of chip pads 120 may include edge pads arranged adjacent to edges of an upper surface of the second semiconductor device 200. Because the second semiconductor substrate 111 and the second semiconductor device 112 are generally similar to the first semiconductor substrate 161 and the first semiconductor device 162, respectively, duplicate descriptions thereof may be omitted. The second semiconductor chip 110 may also include a wiring layer similar to the wiring layer 163 of the first semiconductor chip 160, but the wiring layer may be omitted for convenience of illustration.

The second semiconductor device 112 may include, for example, a memory device. For example, the second semiconductor device 112 may include DRAM or a flash memory.

One end of a plurality of bonding wires 130 may be attached to a chip pad 120 of the plurality of second semiconductor chips 110, and the other end of the plurality of bonding wires 130 may be attached to a plurality of rear surface pads 140. The plurality of bonding wires 130 may directly connect the plurality of chip pads 120 of each of the plurality of second semiconductor chips 110 corresponding to each other to the plurality of rear surface pads 140 of the first semiconductor chip 160. Each of the plurality of second semiconductor chips 110 may be electrically connected to the first semiconductor chip 160 via different bonding wires 130 among the plurality of bonding wires 130.

The plurality of rear surface pads 140 of the first semiconductor chip 160 may be referred to as first chip connection pads, and the chip pad 120 of the second semiconductor chip 110 may be referred to as a second chip connection pad. The bonding wire 130 may connect the first chip connection pad to the second chip connection pad, and may extend from the first chip connection pad to the second chip connection pad.

The die adhesive film 150 may be disposed on and cover the plurality of chip pads 120 of the second semiconductor chip 110 thereunder. One end portion of the plurality of bonding wires 130 respectively connected to the plurality of chip pads 120 may be embedded in the die adhesive film 150. The die adhesive film 150 may include, for example, an inorganic adhesive or a polymer adhesive. The polymer adhesive may include, for example, thermosetting polymer or thermoplastic polymer. In addition, the polymer adhesive may be a hybrid type polymer adhesive manufactured by mixing thermosetting resin or thermoplastic resin.

The plurality of second semiconductor chips 110 may be attached to a portion of the first semiconductor chip 160 vertically overlapping the plurality of second semiconductor chips 110, and the plurality of rear surface pads 140 respectively connected to the plurality of bonding wires 130 may be arranged in the remaining portion of the first semiconductor chip 160 not vertically overlapping with the plurality of second semiconductor chips 110.

Some of the plurality of chip pads 120 included in each of the plurality of second semiconductor chips 110 may include data pads for transmitting a data DQ signal. For example, the number of the data pads of each of the plurality of second semiconductor chips 110 may be about sixteen (16) to about sixty-four (64). In other words, the width of a data bus of each of the plurality of second semiconductor chips 110 may be in a range of from about 16 bits to about 64 bits.

Some of the plurality of rear surface pads 140 of the first semiconductor chip 160 may include data connection pads connected to the data pads of the plurality of second semiconductor chips 110. The data pads of the plurality of second semiconductor chips 110 may be respectively connected to the data connection pads of the first semiconductor chip 160 in a one-to-one manner via different bonding wires 130. That is, the number of data connection pads of the first semiconductor chip 160 may be a result of multiplying the number of the plurality of second semiconductor chips 110 stacked on the first semiconductor chip 160 by the number of data pads of each of the plurality of second semiconductor chips 110. For example, the number of the data connection pads of the first semiconductor chip 160 may be in a range of from about 64 to about 256, and the width of the data bus of the semiconductor package 1 may correspondingly be in a range of about 64 bits to about 256 bits.

In the first semiconductor device 100, the plurality of chip pads 120 of the plurality of second semiconductor chips 110 may be electrically connected to the plurality of rear surface pads 140 of the first semiconductor chip 160 via the plurality of bonding wires 130, and the plurality of rear surface pads 140 may be electrically connected to the first semiconductor device 162 via a plurality of through electrodes (not illustrated). The first semiconductor device 162 may transmit and/or receive data so as to transceive data to and from the outside of the first semiconductor device 162 via the plurality of first connection terminals 172.

The first semiconductor device 100 may further include a molding layer 180 covering the upper surface of the first semiconductor chip 160 and surrounding the plurality of second semiconductor chips 110 and the plurality of bonding wires 130. The molding layer 180 may include, for example, an epoxy mold compound (EMC). In some embodiments, a horizontal width and a horizontal area of the molding layer 180 may be the same as the horizontal width and the horizontal area of the first semiconductor chip 160. For example, the sidewall of the first semiconductor chip 160 and the sidewall of the molding layer 180 may be vertically aligned such that they are coplanar and form a plane.

Each of the plurality of second semiconductor chips 110 may include a memory cell array. The first semiconductor chip 160 may include a physical layer and a direct access region. The physical layer of the first semiconductor chip 160 may include interface circuits for communication with an external host device, and may be electrically connected to the second semiconductor device 200 via the package substrate 400. The first semiconductor device 100 may receive signals from the second semiconductor device 200 or transmit signals to the second semiconductor device 200 via the physical layer. The signals and/or data received via the physical layer of the first semiconductor chip 160 may be transmitted to the plurality of second semiconductor chips 110.

The second semiconductor device 200 may include, for example, a system on chip, a central processing unit (CPU) chip, a graphics processing unit (GPU) chip, or an application processor (AP) chip.

The second semiconductor device 200 may execute applications, supported by the semiconductor package, by using the first semiconductor device 100. For example, the second semiconductor device 200 may execute calculations, such as specialized calculations, by including at least one of a CPU, an AP, a GPU, a neural processing unit (NPU), a tensor processing unit (TPU), a vision processing unit (VPU), an image signal processing unit (ISP), and a digital signal processor (DSP).

The second semiconductor device 200 may include the physical layer and a memory controller. The physical layer of the second semiconductor device 200 may include input/output circuits for transceiving signals to and from the physical layer of the first semiconductor device 100. The second semiconductor device 200 may provide various signals to the physical layer of the first semiconductor device 100 via the physical layer. The memory controller may control the overall operation of the first semiconductor device 100. The memory controller may transmit signals for controlling the first semiconductor device 100 to the first semiconductor device 100 via metal substrate wirings 420 and 430 of the package substrate 400.

The second semiconductor device 200 may transmit/receive (transceiver) electrical signals to/from the first semiconductor device 100 electrically connected thereto via the package substrate 400. A connection wiring 470 in FIG. 1 schematically illustrates a path, through which the first semiconductor device 100 and the second semiconductor device 200 transmit and receive electrical signals to and from each other.

The semiconductor package 1 may further include a package molding layer 500 for molding the first semiconductor device 100, the second semiconductor device 200, and the interposer 300. The package molding layer 500 may include, for example, EMC. In some embodiments, the package molding layer 500 may cover a side surface and an upper surface of the first semiconductor device 100, a side surface of the second semiconductor device 200, and the upper surface 401 of the package substrate 400, but may not cover the upper surface of the second semiconductor device 200.

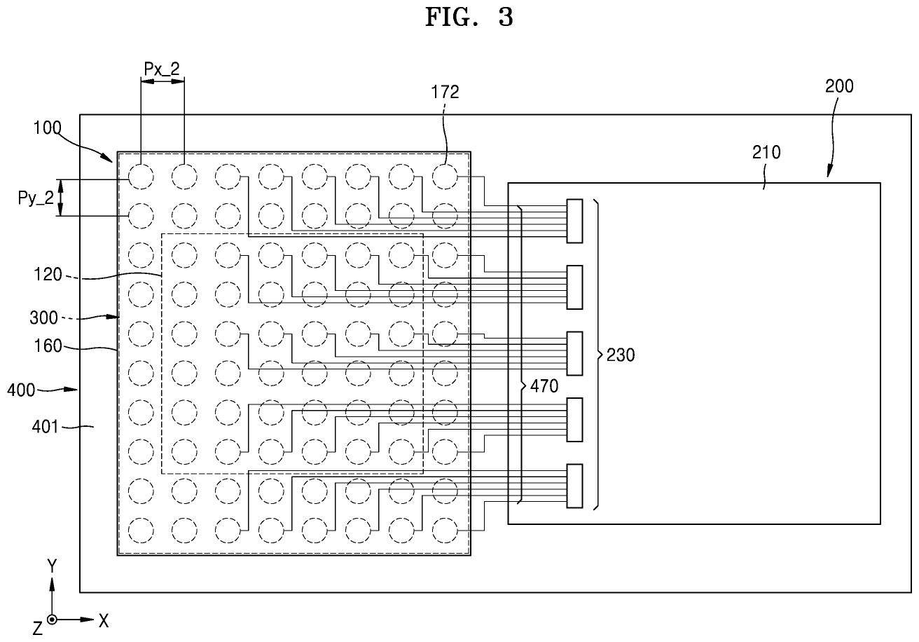

FIG. 3 is a diagram of the semiconductor package 1 according to an embodiment, viewed from above in the −Z axis direction.

Referring to FIG. 3, the second semiconductor device 200 may be mounted on the package substrate 400 as described above. The second semiconductor device 200 may be electrically connected to the plurality of lower pads 210 attached to the lower surface of the second semiconductor device 200 via the plurality of second pads 462 on the package substrate 400. For example, the plurality of lower pads 210 may be electrically connected to the plurality of second pads 462 via the plurality of second connection terminals 220. For example, the plurality of second connection terminals 220 may be solder balls.

The second semiconductor device 200 may transmit/receive electrical signals to/from the first semiconductor device 100 electrically connected thereto via the package substrate 400 and the interposer 300. The electrical signal may be transmitted to the outside via the plurality of first connection terminals 172 below the lower surface of the first semiconductor device 100. The electrical signals passing through a plurality of first connection terminals 172 may reach the second semiconductor device 200 via the connection wiring 470. The electrical signals input/output to/from the second semiconductor device 200 may pass through a physical layer (PHY) interface 230 for signal connection with the outside. At least some of the plurality of first connection terminals 172 may be electrically connected to the PHY interface 230. However, an electrical connection between the plurality of first connection terminals 172 and the PHY interface 230 is not limited thereto.

A shape, in which the first semiconductor device 100 overlaps the upper surface 401 of the package substrate 400, may be referred to as a first shape. A shape, in which the interposer 300 overlaps the upper surface 401 of the package substrate 400, may be referred to as a second shape. For example, as illustrated in FIG. 3, the second shape may have a rectangular shape. In FIG. 3, the second shape is represented by a dashed line inside the periphery of the first semiconductor chip 160. In an embodiment, the second shape and the first shape may both be rectangular shapes and in some embodiments the first shape and the second shape may be the same or substantially similar rectangular shapes. In an embodiment, the first shape and the second shape may have the same or a substantially similar size.

As described above, the first semiconductor device 100 and the second semiconductor device 200 may transceive electrical signals. The electrical signal may be transmitted to the outside via the plurality of first connection terminals 172 below the lower surface of the first semiconductor device 100. The electrical signals passing through a plurality of first connection terminals 172 may reach the second semiconductor device 200 via the connection wiring 470. The electrical signals input/output to/from the second semiconductor device 200 may pass through the PHY interface 230 for signal connection with the outside. At least some of the plurality of first connection terminals 172 may be electrically connected to the PHY interface 230. However, in embodiments, an electrical connection between the plurality of first connection terminals 172 and the PHY interface 230 is not limited thereto.

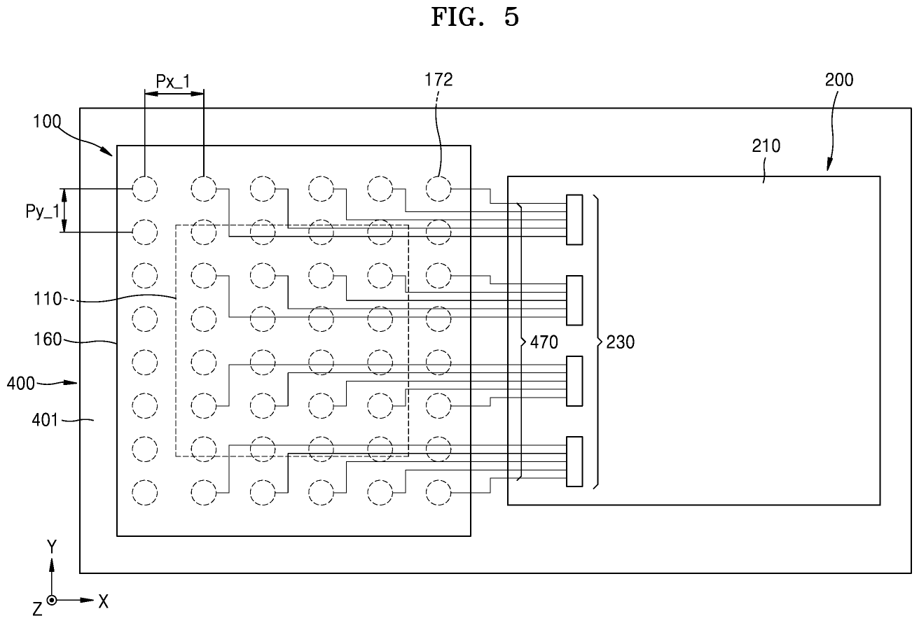

The plurality of first connection terminals 172 may be spaced apart from each other and may be below the lower surface of the first semiconductor device 100. As to be described below with reference to FIG. 5, in a conventional semiconductor package, the plurality of first connection terminals 172 may be spaced apart from each other and may be below the lower surface of the first semiconductor device 100. In a conventional semiconductor package of FIG. 5, the plurality of first connection terminals 172 may be apart from each other at a first x-axis pitch Px_1 in the x-axis direction, and the plurality of first connection terminals 172 may be apart from each other at a first y-axis pitch Py_1 in the y-axis direction.

In the embodiment of FIG. 3 the plurality of first connection terminals 172 may be apart from each other at a second x-axis pitch Px_2, and the plurality of first connection terminals 172 may be apart from each other at a second y-axis pitch Py_2. In an embodiment, the second x-axis pitch Px_2 may be constant, and the second y-axis pitch Py_2 may also be constant. Alternatively, the second x-axis pitch Px_2 and the second y-axis pitch Py_2 may be the same. In an embodiment, the second x-axis pitch Px_2 or the second y-axis pitch Py_2 may be about 100 μm or more, and about 200 μm or less. The pitch between the plurality of connection terminals 350 arranged in the interposer 300 may be about 50 μm or more, and about 100 μm or less. In an embodiment, the pitch between the plurality of second connection terminals 220 under the lower surface of the second semiconductor device 200 may be substantially the same as the pitch between the plurality of connection terminals 350. The connection terminals 350 may also be referred to as a plurality of third connection terminals.

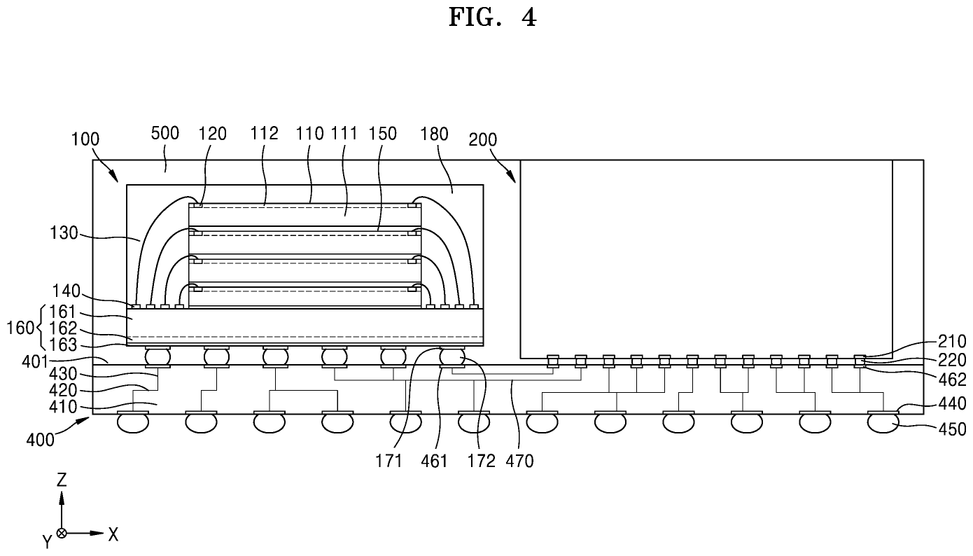

Compared to the pitch between the plurality of first connection terminals 172 in FIGS. 4 and 5 to be described below, the pitch between the plurality of first connection terminals 172 in FIGS. 1 through 3, which are embodiments of the present application, may be less. Similarly, compared to the width of the plurality of first connection terminals 172 in FIGS. 4 and 5, the width of the plurality of first connection terminals 172 in FIGS. 1 through 3, which are embodiments of the present application, may be less. For example, a plurality of first connection terminals 172 may include solder balls. In the case of a solder ball, the width thereof may mean the diameter of the solder ball.

The plurality of first connection terminals 172 of the first semiconductor device 100 may serve as input/output (I/O) ports. When the number of I/O ports in a semiconductor device is increased, a wider bus may be used, and thus, the bandwidth of the semiconductor device may be increased. When the number of the plurality of first connection terminals 172 is increased, the bandwidth between the first semiconductor device 100 and the second semiconductor device 200 may be increased. Comparison of a semiconductor package of an example embodiment with a conventional semiconductor package with respect to bandwidth improvement is described below.

The semiconductor package 1 according to an embodiment of FIGS. 1-3 is compared with a conventional semiconductor package of FIG. 5, which is described below. In the conventional semiconductor package of FIG. 5, the first semiconductor device 100 may be directly electrically connected to the package substrate 400. In the semiconductor package 1 according to an embodiment of FIGS. 1-3, the first semiconductor device 100 may be mounted on the interposer 300, and may be electrically connected to the package substrate 400 via the interposer 300.

The warpage may occur in the first semiconductor device 100 and a package substrate 400. The warpage of semiconductor devices may be determined by thermal expansion coefficient, and configurations and arrangements of elements constituting a device. When the warpage occurs in a semiconductor device, the shape of the warpage of the semiconductor device may have a concave or smile shape, in which a center portion of the semiconductor device is lower than the periphery portion thereof. Alternatively, the shape of the warpage of the semiconductor device may have a convex or cry shape, in which the central portion of the semiconductor device is higher than the periphery portion thereof.

When the warpage occurs in the semiconductor device, a curvature may occur due to bending of the semiconductor device. The curvature may mean a rate of change indicating the degree of bending of a curve or a curved surface. In the case of a curve, when the curvature of the curve is large, the curve may be more bent. That the curvature of the semiconductor device, in which the warpage occurs, is large may mean that the degree of warpage of the semiconductor device is large. As described above, because the degree of warpage may vary depending on the semiconductor device, the curvature of the semiconductor device may also vary.

The semiconductor device may have a particular thermal expansion coefficient. When the thermal expansion coefficient is large, more expansion may occur with respect to the same temperature increase. When the value of the thermal expansion coefficient in at least a portion of the semiconductor device is different from that of the other portion of the semiconductor, the semiconductor device may have the warpage.

As described above, different shapes or different degrees of warpage may occur depending on the semiconductor device. For example, the warpage of the first semiconductor device 100 may occur in a different manner from that of the package substrate 400. Alternatively, the thermal expansion coefficient of the first semiconductor device 100 may be different from the thermal expansion coefficient of the package substrate 400. Accordingly, the configuration and shape of the first semiconductor device 100 may be limited. For example, it may be difficult to reduce the pitches of the plurality of first connection terminals 172 of the first semiconductor device 100. It may be difficult to reduce the sizes of the plurality of first connection terminals 172 of the first semiconductor device 100.

Even though the first semiconductor device 100 may be produced in a smaller size, because a certain level of bandwidth needs to be secured, it may be difficult to reduce the number of the plurality of first connection terminals 172. In addition, due to the occurrence of the warpage described above, it may be limited to reduce the pitch or size of the plurality of first connection terminals 172. In other words, due to issues, such as warpage arising from the connection between the first semiconductor device 100 and the package substrate 400, and the need to maintain performance, it may be difficult to manufacture a relatively small semiconductor device and mount the semiconductor device on the semiconductor substrate.

In an embodiment of the present application, such as shown in FIGS. 1-3, the first semiconductor device 100 may be mounted on the interposer 300. In an embodiment, the interposer 300 may include a silicon interposer. Interposers of silicon single crystals may generate less warpage than substrates. In addition, the silicon interposer may be manufactured more planar than the PCB. In other words, the silicon interposer may have a smaller curvature due to warpage than the first semiconductor device 100 and the package substrate 400. The difference in the degree of coverage between the interposer 300, the package substrate 400, and the interposer 300, and the first semiconductor device 100 may be reduced, compared to the difference in the degree of coverage between the first semiconductor device 100 and the package substrate 400. Accordingly, when the interposer 300 is used, the pitch between the connection terminals due to the warpage effect may be reduced compared to the case, in which the interposer 300 is not used, and thus, the pitch between the connection terminals may be reduced and the size of the connection terminal may be reduced. At the same time, an electrical connection between the first semiconductor device 100 and the package substrate 400 may be maintained via the interposer 300.

In other words, according to embodiments of the present application, including the embodiment shown and described with respect to FIGS. 1-3, the pitch between the plurality of first connection terminals 172 may be reduced, and the width of the plurality of first connection terminals 172 may be used. In other words, the second x-axis pitch Px_2 may be less than the first x-axis pitch Px_1, and the second y-axis pitch Py_2 may be less than the first y-axis pitch Py_1. When the pitch of the plurality of first connection terminals 172 is reduced, and the number of the plurality of first connection terminals 172 is the same, the area, in which the plurality of first connection terminals 172 are arranged, may be reduced.

Because the pitch of the plurality of first connection terminals 172 is reduced, when the area of the lower surface of the first semiconductor device 100 is the same, more numbers of the plurality of first connection terminals 172 may be arranged. The increase of the number of the connection terminals may mean the increase of the I/O ports of the first semiconductor device 100. The increase of the I/O ports of the first semiconductor device 100 may mean higher bandwidths between the first semiconductor device 100 and the second semiconductor device 200, which are electrically connected to each other.

As described above, the electrical signals passing through the plurality of first connection terminals 172 may reach the PHY interface 230 via the connection wirings 470. In an embodiment of the present application, such as shown in FIGS. 1-3, the number of the plurality of first connection terminals 172 corresponding to the I/O port of the first semiconductor device 100 in the embodiment of FIGS. 1-3 may be greater than that of the conventional semiconductor package of FIG. 5. The number of the plurality of first connection terminals 172, which have distance from the second semiconductor device 200 less than a certain distance, may be greater than the number of a conventional semiconductor package. The certain distance may be set according to the needs of a user, and embodiments of the present application are not limited thereto. In other words, the electrical connection distance between the second semiconductor device 200 and the first semiconductor device 100 may be reduced, compared to a conventional semiconductor package. In other words, the average distance between at least some of the plurality of first connection terminals 172 and the PHY interface 230 of the semiconductor package 1 of an embodiment of the present application as shown, for example, in FIGS. 1-3, may be less than that of the conventional semiconductor package of FIG. 5. When an electrical connection distance between the semiconductor device is decreased, signal integrity (SI) may be improved. Accordingly, the semiconductor package 1 according to an embodiment may improve the SI between the first semiconductor device 100 and the second semiconductor device 200.

FIG. 4 is a side view of a typical semiconductor package.

Referring to FIG. 4, a conventional semiconductor package may include the package substrate 400, the first semiconductor device 100 mounted on the package substrate 400, and the second semiconductor device 200. The first semiconductor device 100 may be mounted on the upper surface 401 of the package substrate 400, and the second semiconductor device 200 may be mounted on the upper surface 401 of the package substrate 400 while being apart from the first semiconductor device 100 in the horizontal direction.

The first semiconductor device 100 may be mounted on the package substrate 400. A plurality of lower pads 171 may be arranged on the lower surface of the first semiconductor device 100. The plurality of lower pads 171 may be electrically connected to the semiconductor chips of the first semiconductor device 100. A plurality of lower pads 171 may be electrically connected to the plurality of first pads 461 on the upper surface of the package substrate 400.

The second semiconductor device 200 may be electrically connected to the plurality of lower pads 210 attached to the lower surface of the second semiconductor device 200 via the plurality of second pads 462 on the package substrate 400.

The second semiconductor device 200 may transmit/receive electrical signals to/from the first semiconductor device 100 electrically connected thereto via the package substrate 400. The connection wiring 470 in FIG. 1 schematically illustrates a path, through which the first semiconductor device 100 and the second semiconductor device 200 transceive electrical signals to and from each other. The semiconductor package 1 may further include the package molding layer 500 for molding the first semiconductor device 100 and the second semiconductor device 200.

FIG. 5 is a view of a conventional semiconductor package of FIG. 4, viewed from above in the −Z axis direction. Referring to FIG. 5, the plurality of first connection terminals 172 below the lower surface of the second semiconductor chip 110 included in the first semiconductor device 100 are illustrated by circular dashed lines. The second semiconductor chip 110 of the first semiconductor device 100 is illustrated by a dashed line.

As described above, the plurality of first connection terminals 172 may be apart from each other, and may be below the lower surface of the first semiconductor device 100. In the embodiment, the plurality of first connection terminals 172 may be apart from each other at the first x-axis pitch Px_1, and the plurality of first connection terminals 172 may be apart from each other at the first y-axis pitch Py_1.

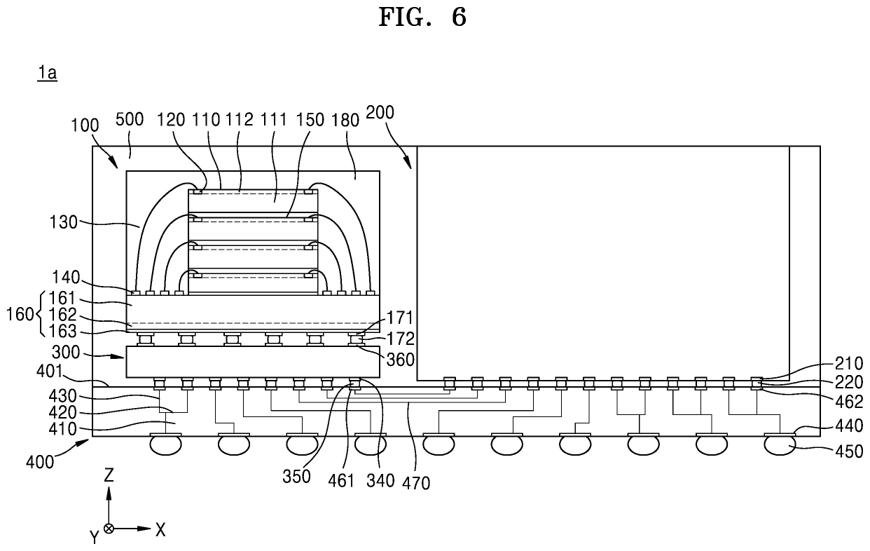

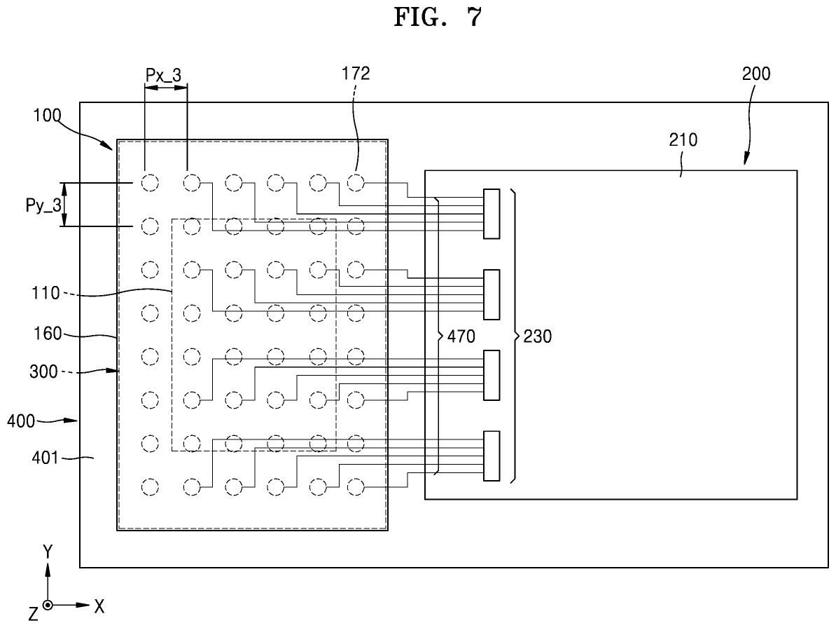

FIG. 6 is a cross-sectional view of a semiconductor package 1a, according to an example embodiment of the present application. FIG. 7 is a diagram of the semiconductor package 1a according to an embodiment, viewed from above in the −Z axis direction. Duplicate descriptions given above are omitted.

Referring to FIGS. 6 and 7, the plurality of first connection terminals 172 may be spaced apart from each other, and may be below the lower surface of the first semiconductor device 100. In the embodiment, the plurality of first connection terminals 172 may be apart from each other at a third x-axis pitch Px_3, and the plurality of first connection terminals 172 may be apart from each other at a third y-axis pitch Py_3. In an embodiment, the third x-axis pitch Px_3 may be constant, and the third y-axis pitch Py_3 may also be constant. Alternatively, the third x-axis pitch Px_3 and the third y-axis pitch Py_3 may have the same value. In an embodiment, the third x-axis pitch Px_3 or the third y-axis pitch Py_3 may be about 100 μm or more, and about 200 μm or less. The pitch between the plurality of connection terminals 350 arranged in the interposer 300 may be about 50 μm or more, and about 100 μm or less. However, the numerical values of the third x-axis pitch Px_3 and the third y-axis pitch Py_3 are not limited thereto.

The number of the plurality of first connection terminals 172 in FIG. 7 may be the same as the number of the plurality of first connection terminals 172 in FIG. 2. In FIG. 7, because the number of connection terminals is maintained, the number of I/O ports of the first semiconductor device 100 may be maintained. Accordingly, the bandwidth of the second semiconductor device 200 electrically connected to the first semiconductor device 100 may be maintained.

As described above with reference to FIG. 2, in embodiments of the present application, the pitch between the plurality of first connection terminals 172 may be reduced, and the size of the plurality of first connection terminals 172 may be reduced, by using example embodiments. In other words, the third x-axis pitch Px_3 may be less than the first x-axis pitch Px_1, and the third y-axis pitch Py_3 may be less than the first y-axis pitch Py_1. When the pitch of the plurality of first connection terminals 172 is reduced, and the number of the plurality of first connection terminals 172 is the same, the area, in which the plurality of first connection terminals 172 are arranged, may be reduced. In other words, the area or size of the first shape may be reduced in the embodiment of FIGS. 6-7. Alternatively, the area of a cross-section or the size of the cross-section on an X-Y plane of the first semiconductor device 100 may be reduced. In other words, in FIG. 7, the first shape may be less than the first shape in FIG. 5. On the X-Y plane, the size of the cross-section of the first semiconductor device 100 in FIG. 7 may be less than the size of the cross-section of the first semiconductor device 100 in FIG. 5.

Because the area or size of the first shape of an example embodiment is decreased while the bandwidth is maintained, the size or area of the package substrate 400, on which the first semiconductor device 100 is mounted, may also be decreased. Because the size or area of the package substrate 400 is reduced, the size or area of the cross-section of the semiconductor package 1a according an embodiment of the present application may be reduced.

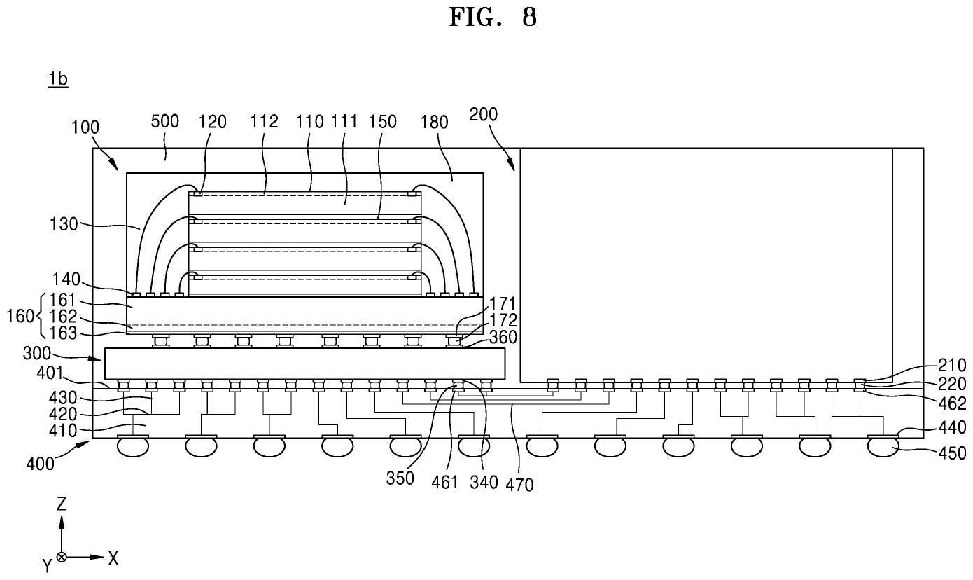

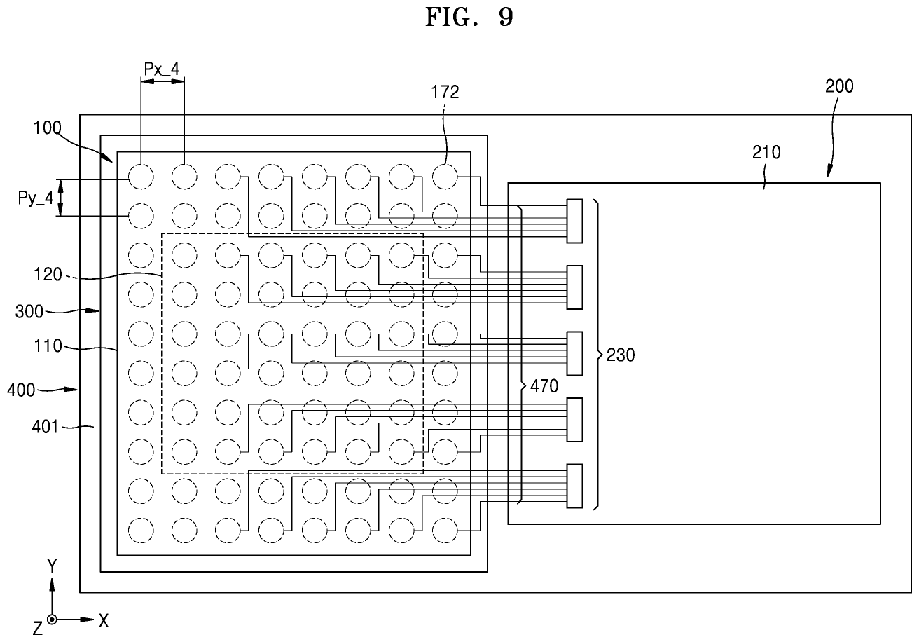

FIG. 8 is a side view of a semiconductor package 1b according to an embodiment. FIG. 9 is a diagram of a semiconductor package according to an embodiment, viewed from above in the −Z axis direction. Duplicate descriptions given above may be omitted.

Referring to FIGS. 8 and 9, the plurality of first connection terminals 172 may be apart from each other at a fourth x-axis pitch Px_4, and the plurality of first connection terminals 172 may be apart from each other at a fourth y-axis pitch Py_4.

A shape, in which the interposer 300 overlaps the upper surface 401 of the package substrate 400, may be referred to as the second shape. The second shape is represented by a dashed line outside the periphery of the first semiconductor chip 160. In an embodiment, like illustrated in FIG. 5, the second region may have the same rectangular shape as the second shape and the first shape described above. The area of the second shape may be greater than the area of the first shape. The length of a side in parallel with the X-axis of the second shape may be greater than or equal to the length of a side in parallel with the X-axis of the first shape. The length of a side in parallel with the Y-axis of the second shape may be greater than or equal to the length of a side in parallel with the Y-axis of the first shape. Alternatively, the outer edge of the second shape may include or be the same as the outer edge of the first shape.

As described above, in the embodiment of FIGS. 8 and 9, the fourth x-axis pitch Px_4 may be less than the first x-axis pitch Px_1. The fourth y axis pitch Py_4 may be less than the first y axis pitch Py_1. As described with reference to FIG. 2, because the pitch between the plurality of first connection terminals 172 are reduced compared to a conventional semiconductor package, the bandwidth between the second semiconductor device 200 and the first semiconductor device 100, which are electrically connected to each other, may be increased.

Because in the embodiment of FIGS. 8 and 9, the second shape is greater than the first shape, the outer edge of the interposer 300 may be greater or wider than the outer edge of the first semiconductor device 100. The cross-sectional area on the X-Y plane of the interposer 300 in FIG. 8 may be greater than the cross-sectional area on the X-Y plane of the interposer 300 in FIG. 5. Alternatively, the size on the X-Y plane of the interposer 300 in FIG. 8 may be greater than the size on the X-Y plane of the interposer 300 in FIG. 5. Accordingly, the number of a plurality of connection terminals 350 arranged below the lower surface of the interposer 300 may be greater than that in FIG. 2.

While aspects of example embodiments have been particularly shown and described, it will be understood that various changes in form and details may be made therein without departing from the spirit and scope of the following claims.

What is claimed is:

1. A semiconductor package comprising:
a first semiconductor device comprising a semiconductor chip;
an interposer comprising silicon and electrically connected to the first semiconductor device, wherein the first semiconductor device is provided on the interposer;
a second semiconductor device; and
a substrate,
wherein the interposer and the second semiconductor device are provided on the substrate and are spaced apart from each other,
wherein the interposer is electrically connected to the second semiconductor device, and
wherein a first volume of a first shape, in which the first semiconductor device overlaps an upper surface of the substrate, is smaller than or equal to a second volume of a second shape, in which the interposer overlaps the upper surface of the substrate.

2. The semiconductor package of claim 1, wherein a first distance between the first semiconductor device and the second semiconductor device, is substantially equal to a second distance between the interposer and the second semiconductor device.

3. The semiconductor package of claim 1, wherein, on an upper surface of the interposer, a plurality of first connection terminals for an electrical connection to the first semiconductor device are provided, and
wherein, under a lower surface of the interposer, a plurality of third connection terminals for electrical connection to the substrate are provided.

4. The semiconductor package of claim 3, wherein a plurality of second connection terminals electrically connect the second semiconductor device to the substrate, and a pitch of the plurality of second connection terminals is substantially equal to a pitch of the plurality of third connection terminals.

5. The semiconductor package of claim 1, wherein the first shape is substantially the same as the second shape.

6. The semiconductor package of claim 1, wherein an outer edge of the first semiconductor device is substantially the same as an outer edge of the interposer.

7. The semiconductor package of claim 1, wherein the first semiconductor device has a convex shape, and the substrate has a concave shape, and
wherein the interposer is electrically connected to the first semiconductor device, and is electrically connected to the substrate.

8. The semiconductor package of claim 1, wherein the first semiconductor device has a concave shape, and the substrate has a convex shape, and
wherein the interposer is electrically connected to the first semiconductor device and the substrate having.

9. The semiconductor package of claim 1, wherein a curvature of the interposer is less than a curvature of the first semiconductor device and a curvature of the substrate.

10. The semiconductor package of claim 9, wherein the first semiconductor device and the substrate have a concave shape or a convex shape, and the curvature of the first semiconductor device and the curvature of the substrate are different from each other.

11. The semiconductor package of claim 1, wherein a thermal expansion coefficient of the first semiconductor device is different from a thermal expansion coefficient of the substrate.

12. The semiconductor package of claim 3, wherein a pitch of the plurality of first connection terminals is equal to or greater than a pitch of the plurality of third connection terminals, and
wherein a width of the plurality of first connection terminals is equal to or greater than a width of the plurality of third connection terminals.

13. The semiconductor package of claim 1, further comprising a molding layer around the first semiconductor device, the second semiconductor device, and the interposer,
wherein side surfaces of the second semiconductor device are surrounded by the molding layer, and an upper surface of the second semiconductor device is exposed.

14. A semiconductor package comprising:
a first printed circuit board (PCB) substrate electrically connected to the outside;
a memory package comprising the first printed circuit board (PCB) substrate and memory chips stacked on the first printed circuit board (PCB) substrate;
a silicon interposer electrically connected to the first printed circuit board (PCB) substrate;
a logic chip spaced apart from the memory package and the silicon interposer; and
a second printed circuit board (PCB) substrate having the silicon interposer and the logic chip provided thereon, and electrically connected to the silicon interposer and the logic chip.

15. The semiconductor package of claim 14, wherein a plurality of first connection terminals configured to be electrically connected to the first printed circuit board (PCB) substrate are disposed on an upper surface of the silicon interposer, and
wherein a plurality of third connection terminals configured to be electrically connected to the second printed circuit board (PCB) substrate are disposed under a lower surface of the silicon interposer.

16. The semiconductor package of claim 14, wherein the first printed circuit board (PCB) substrate and the second printed circuit board (PCB) substrate each have a convex or concave shape.

17. The semiconductor package of claim 14, wherein a curvature of the first printed circuit board (PCB) substrate is equal to or different from a curvature of the second printed circuit board (PCB) substrate, and a curvature of the silicon interposer is less than the curvature of the first printed circuit board (PCB) substrate and the curvature of the second printed circuit board (PCB) substrate.

18. The semiconductor package of claim 15, wherein a pitch between the plurality of first connection terminals is about 100 μm or more, and about 200 μm or less, and
wherein the pitch between the plurality of third connection terminals is about 50 μm or more, and about 100 μm or less.

19. A semiconductor package comprising:
a first printed circuit board (PCB) substrate;
a memory package comprising the first printed circuit board (PCB) substrate and memory chips stacked on the first printed circuit board (PCB) substrate;
a silicon interposer electrically connected to the first printed circuit board (PCB) substrate;
a logic chip spaced apart from the memory package and the silicon interposer; and
a second printed circuit board (PCB) substrate comprising the silicon interposer and the logic chip mounted thereon, and electrically connected to the silicon interposer and the logic chip,
wherein a plurality of first connection terminals configured to be electrically connected to the first PCB substrate are provided on an upper surface of the silicon interposer, and a plurality of third connection terminals configured to be electrically connected to the second PCB substrate are provided under a lower surface of the silicon interposer, and
wherein a curvature of the first printed circuit board (PCB) substrate is equal to or different from a curvature of the second printed circuit board (PCB) substrate, and a curvature of the silicon interposer is less than the curvature of the first printed circuit board (PCB) substrate and the curvature of the second printed circuit board (PCB) substrate.

20. The semiconductor package of claim 19, wherein a pitch of the plurality of first connection terminals is greater than a pitch of the plurality of third connection terminals,
wherein a width of the plurality of first connection terminals is greater than a width of the plurality of third connection terminals, and
wherein a first shape, in which the memory package overlaps an upper surface of the second printed circuit board (PCB) substrate, is substantially the same as a second shape, in which the interposer overlaps the upper surface of the second printed circuit board (PCB) substrate.
